(19) United States
(12) Patent Application Publication
(10) Pub. No.: US 2003/0181337 A1
(43) Pub. Date: Sep. 25, 2003

(54) Layer deposition on superconductor particles by sputtering or evaporation

(76) Inventor: Matthew J. Holcomb, Manhattan Beach, CA (US)

Correspondence Address: Stephen M. De Klerk, Blakely, Sokoloff, Taylor & Zafman LLP, Seventh Floor, 12400 Wilshire Boulevard, Los Angeles, CA, 90025-1030, US

(21) Appl. No.: 10/328,961

(22) Filed: Dec. 24, 2002

Related U.S. Application Data
(63) Continuation of application No. PCT/US01/41145, filed on Jun. 25, 2001.

(51) Int. Cl. C23C 14/32; B05D 1/12; B05D 7/00; H01L 39/24; B05D 5/12

(52) U.S. Cl. 505/473; 427/212; 427/180; 204/192.24; 204/298.29; 204/298.23; 204/298.24; 505/475; 505/476

(57) ABSTRACT

A plurality of superconductor particles are formed being of a first material which is relatively brittle and is selected to be in a superconductive state at a relatively high temperature, typically above 77K which is the temperature of liquid nitrogen. A coating layer is formed on each superconductor particle, the coating layer being of a second material selected to be substantially non-reactive with the first material. The coated particles are then mixed with a third material to form a composite wherein the third material is in proximity to the first material but separated by the second material. The third material is selected to be relatively ductile when compared to the first material and to be driven to a superconductive state by the first material when the first material is in a superconductive state and the third material is in proximity to the first material. The second material protects the third material from oxidation by the first material. The second material is selected and is sufficiently thin to allow for the third material to be driven to the superconductive state by the first material through the second material. The invention relates to a method and apparatus for forming coating layers on the superconductor particles utilizing for example sputtering or evaporation.

### CROSS-REFERENCE TO RELATED APPLICATIONS

The present patent application is a continuation of PCT/US01/41145 filed on Jun. 25, 2001, which claims the benefit of U.S. patent application Ser. No. 09/604,857 filed on Jun. 27, 2000, which is a continuation-in-part of U.S. Pat. No. 6,420,318 filed on Nov. 4, 1999, which is a continuation-in-part of U.S. Pat. No. 5,998,336 filed on Feb. 26, 1997, all of which are incorporated herein by reference in their entirety.

### BACKGROUND OF THE INVENTION

1). Field of the Invention

This invention relates to a method and apparatus for producing a superconductor property composite.

2). Discussion of Related Art

U.S. Pat. No. 5,998,336 describes principles relating to the manufacture of a superconductor property composite utilizing the proximity effect. A plurality of superconductor particles are formed being of a first material which is relatively brittle and is selected to be in a superconductive state at a relatively high temperature, typically above 77K which is the temperature of liquid nitrogen. A coating layer is formed on each superconductor particle, the coating layer being of a second material selected to be substantially non-reactive with the first material. The coated particles are then mixed with a third material to form a composite wherein the third material is in proximity to the first material but separated by the second material. The third material is selected to be relatively ductile when compared to the first material and to be driven to a superconductive state by the first material when the first material is in a superconductive state and the third material is in proximity to the first material. The second material protects the third material from oxidation by the first material. The second material is selected and is sufficiently thin to allow for the third material to be driven to the superconductive state by the first material through the second material.

The need has arisen to develop a method and apparatus for forming coating layers on the superconductor particles.

### SUMMARY OF THE INVENTION

According to one aspect of the invention a method for producing a superconductor property composition is provided. A plurality of superconductor particles are formed, the superconductor particles being of a first material being relatively brittle and being selected to be in a superconductive state above 10K. Coating particles from a source of coating particles of a second material are directed to the superconductor particles, thereby at least partially coating a surface of each superconductor particle with an initial coating layer to form a plurality of partially coated particles. Each partially coated particle is then rotated relative to the source, resulting in rotated particles. Coating particles from the source of coating particles are then directed towards the rotated particles, thereby further coating the respective surface of each superconductor particle with a further coating layer to form a plurality of further coated particles.

The further coated particles may be located in proximity to a third material to form the composition. The third material may be selected to be relatively ductile when compared to the first material and to be driven to a superconductive state by the first material when the first material is in a superconductive state and the third material is in proximity to the first material. The second material is selected to be substantially non-reactive with the first material and is sufficiently thin to allow for the third material to be driven to a superconductive state by the first material through the second material.

The invention also provides a method for producing a superconductive property composition, comprising forming a plurality of superconductor particles of a first material being relatively brittle and being selected to be in a superconductive state above 10K, locating the superconductor particles in a chamber, introducing gas particles into the chamber, creating a voltage on a sputter target, the sputter target being located in the chamber and being made of a second material, the gas particles being ionized and then attracted to the sputter target due to the voltage being created on the sputter target, the gas ions colliding with the sputter target so that the coating particles of the second material are released from the sputter target and directed from the sputter target to the superconductor particles so that the surface of each superconductor particle is coated with a layer to form a plurality of coated particles.

According to another aspect of the invention, a method for producing a superconductor property composition is provided, comprising forming a plurality of superconductor particles of a first material being relatively brittle and being selected to be in a superconductive state above 10K, dropping the superconductor particles from a higher elevation to a lower elevation through a volume under a force of gravity, directing coating particles from a source of coating particles of a second material to the superconductor particles while dropping through the volume, thereby coating a surface of each superconductor particle with a coating layer to form a plurality of coated particles, and catching the superconductor particles at the lower elevation.

The invention also provides a method for producing a superconductor property aggregate comprising forming a plurality of superconductor particles of a first material being relatively brittle and being selected to be in a superconductive state above 10K, and simultaneously directing coating particles of a second material onto each superconductor particle from a first direction and from a second direction being at an angle relative to the first direction, thereby simultaneously coating a surface of the superconductor particle in both the first and second directions with a coating layer.

The invention also provides a method for producing a superconductive property composition, comprising forming a plurality of superconductor particles of a first material being relatively brittle and being selected to be in a superconductive state above 10K, and applying a coating layer on a surface of each superconductor particle to form a plurality of coated particles, the coating layers being applied with the superconductor particles of a temperature of below 500° C.

The invention also provides apparatus for coating a plurality of superconductor particles comprising a chamber, a container, a source of gas particles, a sputter target, a voltage source, and a stirring device. The container is located within the chamber with purposes of holding the superconductor particles. The source of gas particles introduces gas particles into the chamber. The sputter target is located in the chamber. The voltage source is coupled to the sputter target so as to create a voltage on the sputter target. The gas particles are ionized and then attracted to the sputter target due to the voltage and collide with the sputter target so that coating particles are released from the sputter target. The coating particles have movement directed towards the superconductor particles so that a coating layer is formed on a surface of at least some of the superconductor particles. The stirring device is connected to the particles so as to stir the superconductor particles in order to ensure coverage of coating layers on more of the particles than without stirring.

The invention also provides apparatus for coating a plurality of superconductor particles comprising a chamber, a higher container, a lower container, and a source of coating particles. The higher container is for holding and dropping the superconductor particles from a high elevation to a lower elevation through a volume in the chamber under a force of gravity. The lower container is located at the lower elevation to catch the superconductor particles after dropping through the volume. The source of coating particles are of a second material. The coating particles are directed from the source to the superconductor particles while dropping through the volume, thereby coating a surface of each superconductor particle with a coating layer to form a plurality of coated particles.

The invention also provides apparatus for coating a plurality of superconductor particles comprising a chamber, a container, a heating element, a voltage source, and a material within the chamber. A container is located within the chamber for holding the superconductor particles. The heating element is located within the chamber. The voltage source is coupled to the heating element so that the heating element heats up when the voltage source is operated. The material is located within the chamber and is being heated by the heating element, heating of the material causing evaporation thereof into coating particles. The coating particles form a layer on the superconductor particles. The material may be selected from the group consisting of silver and its alloys, niobium and its alloys, a niobium titanium alloy, lead and its alloys, a lead bismuth alloy, tin and its alloys, and indium and its alloys.

### BRIEF DESCRIPTION OF THE DRAWINGS

The invention is further described by way of examples with reference to the accompanying drawings wherein:

FIG. 1 is a cross-sectional side view of apparatus for coating a plurality of particles, according to one embodiment of the invention;

FIG. 2 is a view of superconductor particles which are sputtered with an initial coating layer utilizing the apparatus of FIG. 1;

FIG. 3 is a view similar to FIG. 2 after the superconductor particles are stirred;

FIG. 4 is a view similar to FIG. 3 after a further coating layer is sputtered on the superconductor particles;

FIG. 5 is a view similar to FIG. 4 after further stirring and sputtering onto the superconductor particles;

FIG. 6 is a cross-sectional side view of a wire made out of a three component composition including coated particles of FIG. 5 which are mixed with a ductile material;

FIG. 7 is a cross-sectional side view of apparatus for coating a plurality of particles, according to another embodiment of the invention;

FIG. 8 is a side view of one superconductor particle which is sputtered with an initial coating layer utilizing the apparatus of FIG. 7;

FIG. 9 is a view similar to FIG. 8 after the superconductor particle is rotated as it falls through a volume defined within the apparatus of FIG. 7;

FIG. 10 is a view similar to FIG. 9 after a further coating layer is sputtered onto the superconductor particle;

FIG. 11 is a view similar to FIG. 10 after further rotation of and deposition onto the superconductor particle, with recirculation as required;

FIG. 12 is a cross-sectional side view of apparatus for coating a plurality of particles, according to a further embodiment of the invention;

FIG. 13 is a cross-sectional side view of apparatus for coating a plurality of particles, being a modification of the apparatus of FIG. 12;

FIG. 14 illustrates coated superconductor particles which are loosely arranged without a material between them; and

FIG. 15 illustrates the superconductor particles after they are compressed into a two component composition.

### DETAILED DESCRIPTION OF THE INVENTION

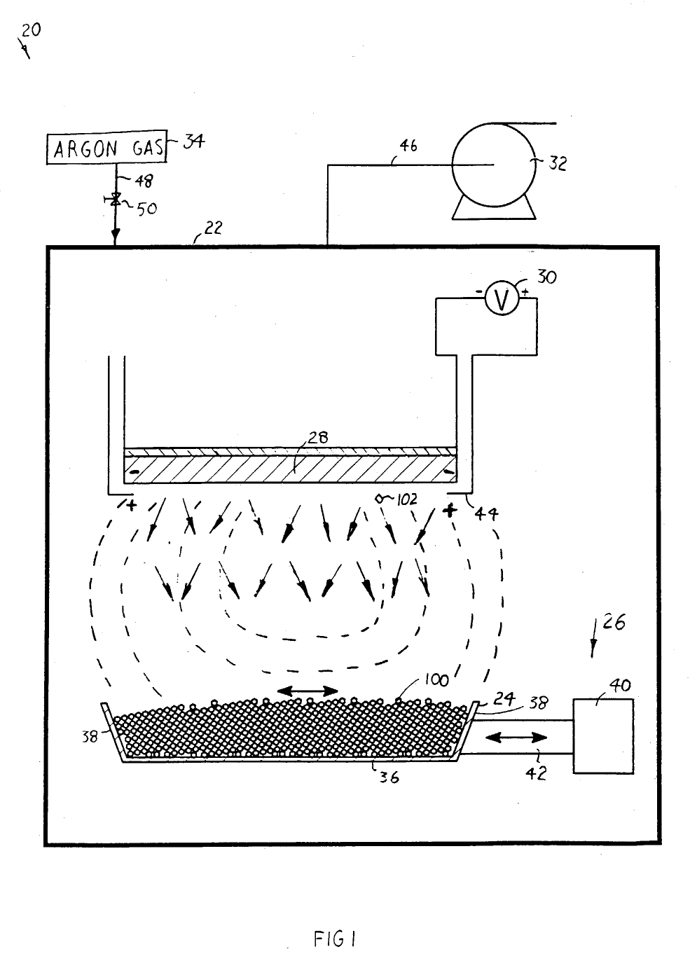

FIG. 1 of the accompanying drawings illustrates apparatus 20 for plating a plurality of superconductor particles, according to an embodiment of the invention. The apparatus 20 includes a chamber 22, a container 24, a stirring device 26, a sputter target 28, and a voltage source 30 within the chamber 22, and a pump 32 and an argon gas supply 34 located outside the chamber 22.

The container 24 has a relatively wide base 36 near a base of the chamber 22, and sides 38 extending upwardly from the base 36. The stirring device 26 includes an actuator 40 and a link 42. The link 42 has one end connected to the actuator 40. The actuator 40 may for example be an electric motor with an eccentric shaft which vibrates the link 42. The link 42 is preferably vibrated in at least first and second transverse directions, such as in a circle. Another end of the link 42 is connected to the container 24. Any movement of the link 42 is transferred to the container 24. The container 24 is therefore also moved or vibrated in first and second transverse directions when the actuator 40 is operated.

The sputter target 28 is located above the container 24 and a conductive ring 44 is located below a periphery of the sputter target 28. The sputter target 28 is connected to a negative terminal of the voltage source 30 and the ring 44 is connected to a positive terminal of the voltage source 30.

The pump 32 is connected via a line 46 to the chamber 22. Operation of the pump 32 causes a reduction in pressure within the chamber 22.

The argon gas source 34 is connected to the chamber 22 via a line 48 having a valve 50 located therein. The argon gas source 34 may for example be a pressurized cylinder filled with argon gas. Opening or closing of the valve 50 may control flow of argon gas particles into the chamber 22.

In use, the container 24 is filled with a plurality of ceramic superconductor particles 100. U.S. Pat. No. 5,998,336, which is incorporated herein by reference, describes how the particles 100 can be formed and the materials that they are made of. Suffice to say that they are relatively brittle ceramic particles and that they generally have superconductor critical temperatures (T_{c}) between 10K and 130K, including individual temperatures in between.

The pump 32 is operated so that the pressure within the chamber 22 reduces to about 10-7 torr. The valve 50 is then opened and a small amount of argon gas flows from the argon gas source 34 through the valve 50 into the chamber 22 resulting in an increase in pressure to about 10-3 torr. Argon gas particles are ionized to Ar⁺ ions and then attracted to the sputter target 28 because of the negative voltage that is applied to the sputter target 28. The voltage source 30 is then energized which turns the sputter target 28 into a cathode and the ring 44 into an anode. In accordance with general principles relating to sputter deposition, the argon ions collide with a lower surface of the sputter target 28, resulting in release of coating particles 102 from the sputter target 28. The coating particles 102 have high kinetic energy, but numerous collisions with gas particles in the chamber 22 both lower the energy of the coating particles and randomize the trajectories of the coating particles. The velocity of the coating particles 102 is primarily directed downwardly towards the superconductor particles 100.

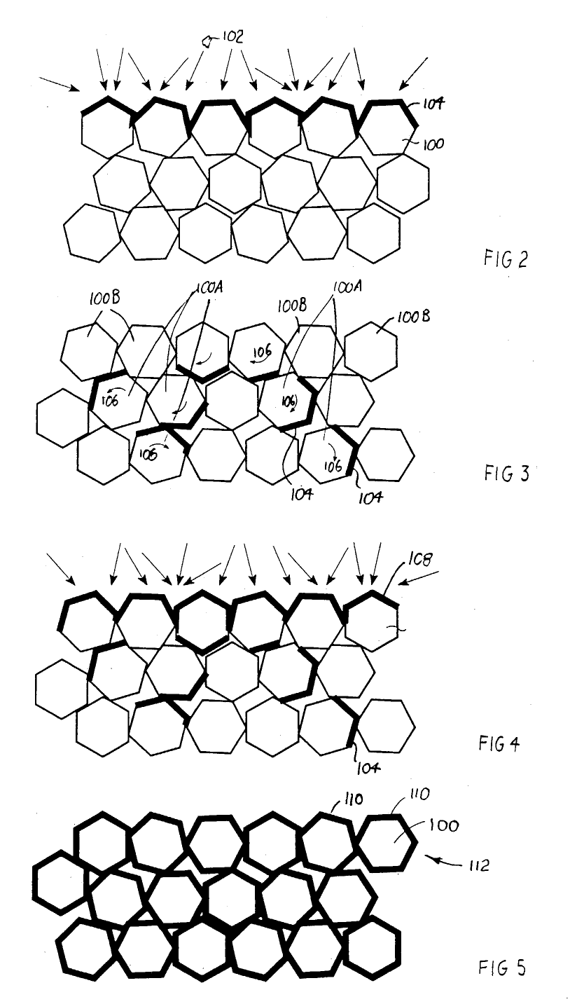

Reference is now made to FIG. 1 in combination with FIG. 2 to FIG. 5. FIG. 2 illustrates the superconductor particles 100 during an initial coating by the coating particles 102. The coating particles 102 form an initial coating layer 104 on each of upper ones of superconductor particles 100. The directions of movement of many of the coating particles 102 change as they approach the superconductor particles 100 between the sputter target 28 and the superconductor particles 100, due to multiple collisions between respective ones of the coating particles 102 and with argon gas particles the directions of movement of the coating particles 102 are thus multidirectional before they collide with the superconductor particles 100. This has the advantage that initial coating layers 104 can be formed on surfaces that are not entirely horizontal. It is therefore possible to form the initial coating layers 104 also on surfaces that are vertical or substantially vertical to the same extent that they are formed on horizontal surfaces. A larger area of one of the superconductor particles 100 is thereby more uniformly coated than when the direction of movement of the coating particles 102 are unidirectional.

The actuator 40 is continuously operated while the superconductor particles are being sputtered. FIG. 3 illustrates what happens to the superconductor particles 100, sputtered as shown in FIG. 2, after being stirred due to operation of the actuator 40. Some of the superconductor particles 100A sputtered as shown in FIG. 2, move down while other ones of the superconductor particles 100B move up. Stirring also causes rotation of some or all of the particles sputtered as shown in FIG. 2 in directions 106 relative to the position of the sputter target 28. As a result, previously unsputtered surfaces of the superconductor particles 100 are exposed to the top and therefore towards the sputter target 28.

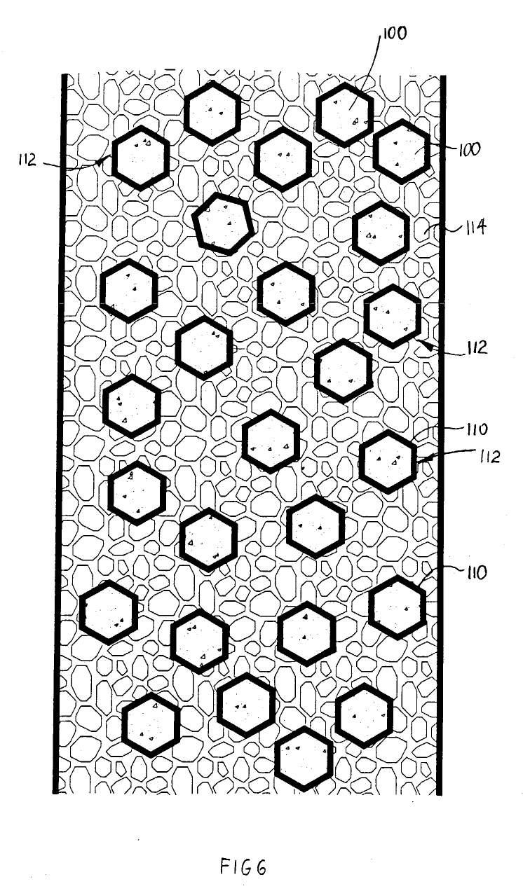

FIG. 4 illustrates the arrangement of superconductor particles of FIG. 3 after further sputtering. Although FIG. 4 is shown separate from FIG. 3, it should be understood that the steps carried out in FIGS. 3 and 4 may occur simultaneously. In FIG. 4, the exposed upper surfaces of the superconductor particles located at the top are sputtered as in FIG. 2. More surfaces of more of the superconductor particles 100 are thereby covered with further coating layers 108.

By repeating the process shown in FIG. 3 and FIG. 4, all or substantially all surfaces of the superconductor particles 100 can be covered with enveloping coating layers 110 as shown in FIG. 5. The combination of the superconductor particles 100 and the coating layers 110 are hereinafter referred to as ”coated particles 112”.

As illustrated in FIG. 6 and further described in U.S. Pat. No. 5,998,336, the coated particles 112 are mixed with a material 114 and drawn into wire having a three component composition. The material 114 is chosen to be relatively ductile when compared to the material of the superconductor particles 100. As such, the material 114 provides ductility to the wire. In general, the material 114 becomes superconductive at temperatures much lower than the relatively high temperatures that the superconductor particles 100 become superconductive. Lead is an example of a material which can be used for the material 114. As described in U.S. Pat. No. 5,998,336, the superconductor particles 100 can drive the material 114 to a superconductive state if the material 114 is in close proximity to the superconductor particles 100. In addition, the material of the coating layers 110 has to be sufficiently thin and be selected of a material which allows for the material 114 to be driven to a superconductive state by the superconductor particles 100. An example of the material of the coating layers 110 (and therefore also of the sputtered target 28 in FIG. 1) is silver. The main purpose of the coating layers 110 is to protect the material 114 from oxidation by the superconductor particles 114 when in the composite shown in FIG. 6 and also to protect the superconductor particles 100 from environmental oxidation before being mixed into the composite of FIG. 6.

As mentioned, an advantage of the use of the apparatus of FIG. 1 is that the coating particles shown in FIG. 2 deposit from different sides onto each superconductor particle 100. Another advantage is that the superconductor particles remain at a relatively low temperature during the coating process, typically about 200° C. A temperature below 500° C. of the superconductor particles 102 is particularly beneficial because of a substantially reduced likelihood that the material of the superconductor particles 100 will lose oxygen and thus their superconducting properties.

One disadvantage of the apparatus of FIG. 1 is that the sputter target 28 has to be replaced from time to time. Furthermore, it may be difficult to mix the superconductor particles 100 to an extent which ensures suitable and uniform forming of coating layers 110 at a relatively high throughput rate. A further disadvantage of the use of the apparatus 20 is that it does not lend itself to continuous commercial production because the container 24 continually has to be removed from the chamber 22 in order to replace coated particles with uncoated superconductor particles.

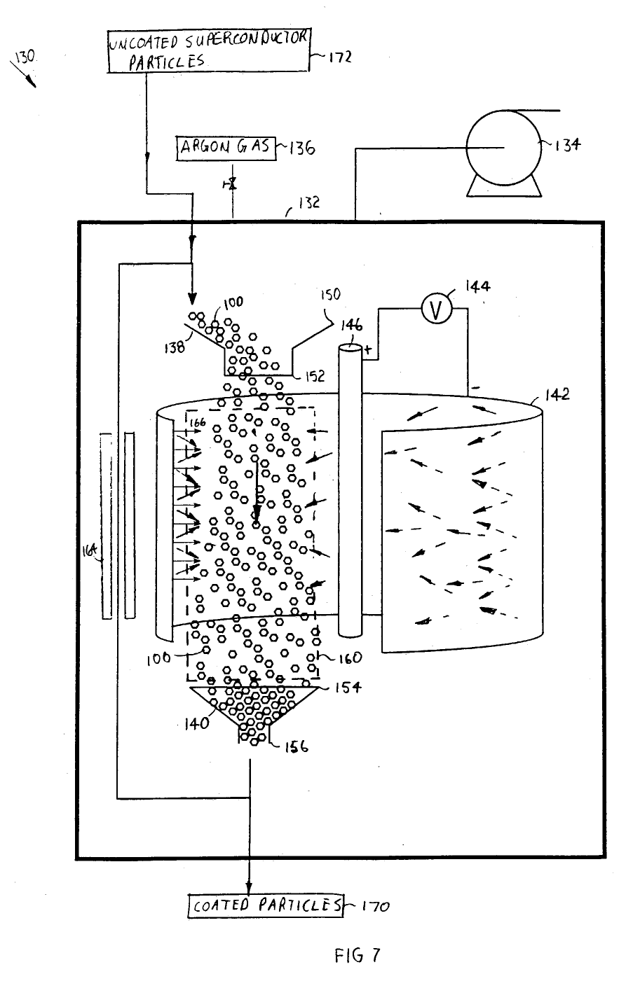

FIG. 7 illustrates an alternative apparatus 130 which may overcome many of the disadvantages associated with the apparatus 20 of FIG. 1. The apparatus 130 includes a chamber 132, a pump 134, and an argon gas supply 136, serving the same purposes and being operated the same as the chamber 22, pump 32, and argon gas supply 34, respectively, of the apparatus 20 in FIG. 1. The apparatus 130 further includes an upper container 138, a lower container 140, a cylindrical sputter target 142, a voltage source 144, and a conductive pin 146.

The upper container 148 is in the form of a funnel having a large upper area 150 and a small lower mouth 152. The lower container 140 is also in the form of a funnel having a large upper area 154 and a small lower mouth 156. The upper container 138 is located at a higher elevation and the lower container 140 is located at a lower elevation below the upper container 138. An imaginary volume 160 is defined having a height extending from the upper area 154 of the lower container 140 to the lower mouth 152 of the upper container 138, and a width corresponding to a width of the upper area 154 of the lower container 140.

The cylindrical sputter target 142 extends vertically through the chamber 132. The conductive pin 146 is located centrally within the cylindrical sputter target and extends vertically through the cylindrical sputter target 142. The volume 160 is located between the pin 146 and one side of the cylindrical sputter target 142. When viewed from above, the cylindrical sputter target 142 entirely encircles and encloses the volume 160. The cylindrical sputter target 142 is thus located on all sides of the volume 160 when viewed from above.

The cylindrical sputter target 142 is connected to a negative terminal of the voltage source 142 and the pin 146 is connected to a positive terminal of the voltage source 142. The voltage source 142 serves the same purpose as the voltage source 30 of the apparatus 20 in FIG. 1.

In use, argon ions collide with a surface of the cylindrical sputter target 142, causing release of coating particles from the cylindrical sputter target 142. A transporting device 164 such as a conveyor transports superconductor particles 100 to the upper area 150 of the upper container 138. The superconductor particles 100 move through the upper container 138 to the lower mouth 152 thereof and then drop from the mouth 152 through the volume 160. The superconductor particles 100 are collected by the upper area 154 of the lower container 140 which catches the superconductor particles 100 and can move through the lower container 140 to the lower mouth 156 thereof, whereafter they are again collected by the transporting device 164 and transported and delivered to the upper container 138.

The coating particles released from the cylindrical sputter target 142 move in generally a horizontal direction 166 into the volume 160 and attach to the superconductor particles 100. Some of the coating particles may move through the volume 160 without attaching to any of the superconductor particles 100 and attach to an opposing side of the cylindrical sputter target 142.

An advantage of the apparatus 130 is that it is suitable for large-scale production. One reason why it is suitable for large-scale production is because it can be scaled so that the volume 160 is sufficiently high to accommodate a required number of superconductor particles. Another reason why it is suitable for large-scale production purposes is because large amounts of superconductor particles can be collected in the containers 138 and 140 and be fed through the volume 160 as required.

A further reason why the apparatus 130 of FIG. 7 has commercial applicability is that there is no need to remove any containers from the chamber 132. Coated particles 170 can simply be extracted from the lower container 140 simply directing them to an opening out of the chamber 132. A valve mechanism (not shown) may also be provided which ensures that a negative pressure within the chamber 132 is maintained when the coated particles 170 are removed. Once the coated particles 170 are removed, uncoated superconductor particles 172 may be introduced into the system and be fed to the upper container 138.

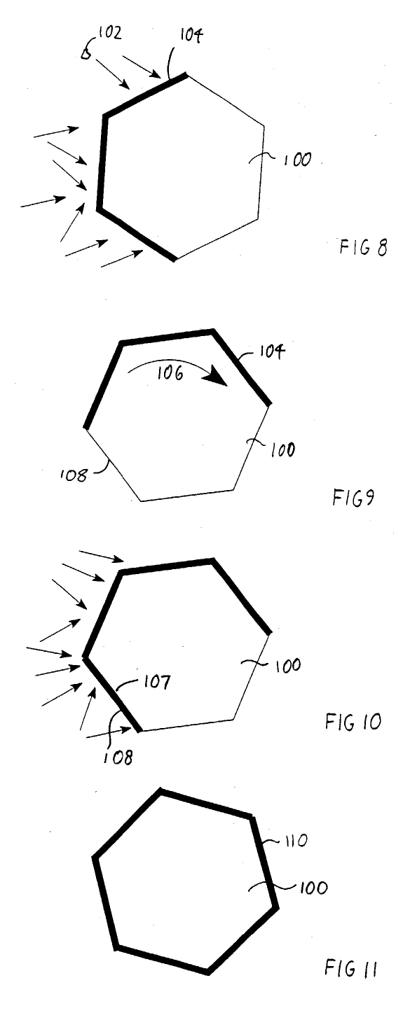

FIG. 8 to FIG. 11 now illustrate how one superconductor particle 100 is coated utilizing the apparatus 130 of FIG. 7.

As shown in FIG. 8, coating particles 102 have velocities in multiple directions just before contacting the superconductor particle 100. The coating particles 102 thus contact the superconductor particle 100 from multiple directions which are at angles relative to one another. Faces of the superconductor particle 100 which are at angles relative to one another are thus covered with an initial coating layer 104. It should be noted that a left side of the superconductor particle facing towards a closest wall of the cylindrical sputter target 142 is covered more with an initial layer 104 than a right side of the superconductor particle 100 facing away from the closest wall of the cylindrical sputter target 142.

As shown in FIG. 9, the superconductor particle 100 rotates in a direction 106 falling through the volume 160. A number of factors may contribute to rotation in a direction 106 of the superconductor particle 100 including collisions between the superconductor particle 100 and other superconductor particles or with some of the coating particles 102, the location of the center of gravity of the superconductor particle 100, especially once the initial coating layer 104 is formed, or rotation induced by the upper container 138 onto the superconductor particle 100. The result of the rotation in the direction 106 is that a face 107 of the superconductor particle 100, which is not coated is step shown in FIG. 8, is exposed to a closest wall of the cylindrical sputter target 142.

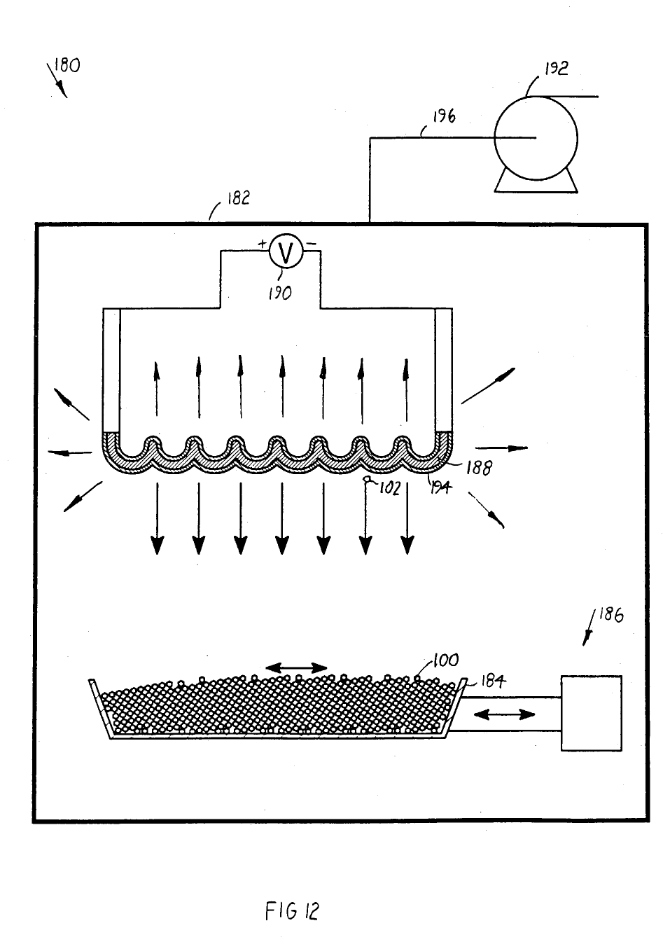

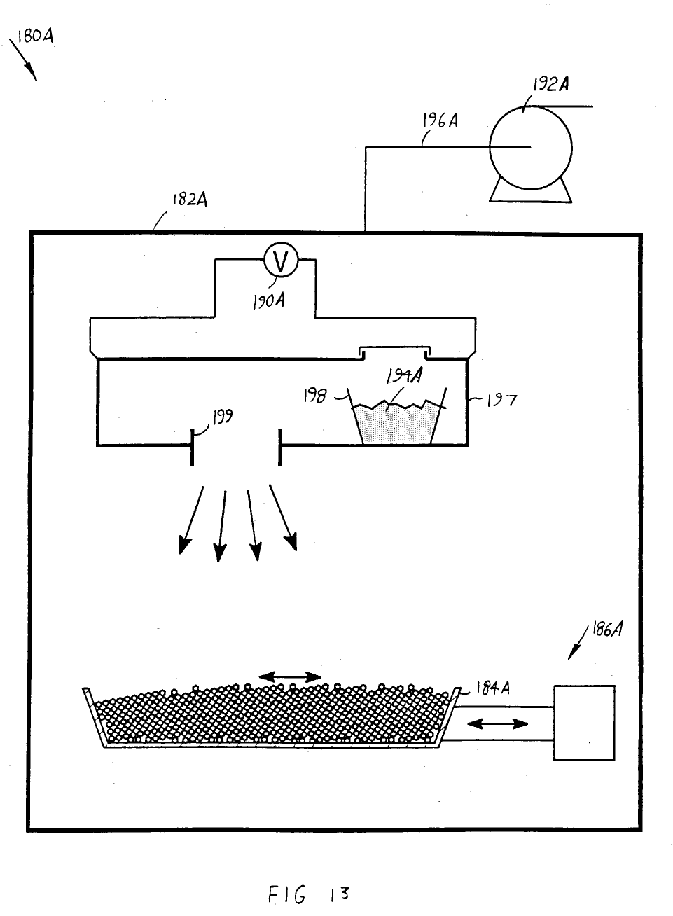

FIG. 10, illustrates a step that is typically carried out together with the step illustrated in FIG. 9. The superconductor particle 100 is further coated with a further coating 108 on the exposed surface 107. Further rotation and coating of the superconductor particle 100 results in coating 110 which entirely envelops the superconductor particle 100 as shown in FIG. 11. Depending on the dimensions of the components of the apparatus 130, in particular the volume 160, and other processing conditions, it may occur that the superconductor particle 100 is not sufficiently enveloped by a coating layer 110. In such a case, the partially coated superconductor particles are returned and recirculated utilizing the transporting device 164.

FIG. 7 illustrates one example of a drop through sputtering apparatus that may be used. Other devices may be alternatively used such as a cylindrical magnetron sputtering gun. A cylindrical magnetron sputtering gun utilizes a cylindrical sputter target such as the cylindrical sputter target 142 of FIG. 7 which is connected to a negative terminal of a voltage source. An additional cylinder is located around the cylindrical sputter target thereof which is connected to a positive terminal of the voltage source. The additional cylinder replaces the function of the pin 146 of FIG. 7.

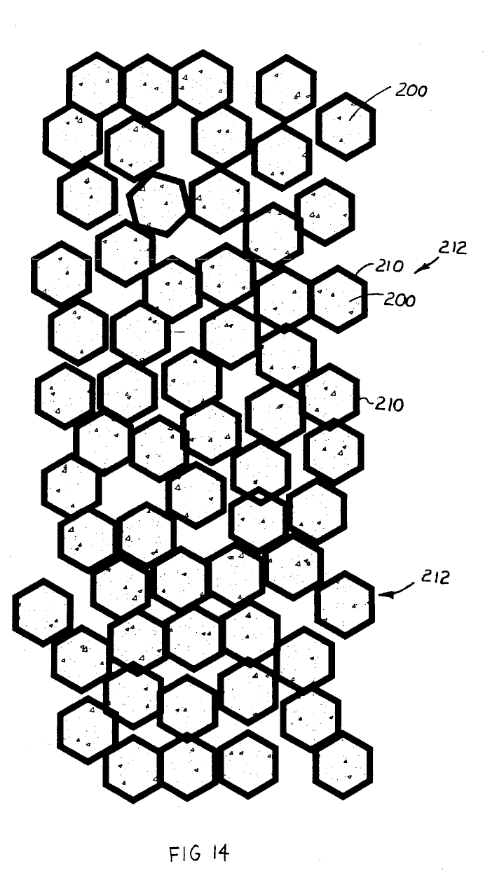

FIG. 12 illustrates a further apparatus 180 that can be used for coating superconductor particles. The apparatus 180 includes a chamber 182, a container 184, a stirring device 186, a heating element 188, and a voltage source 190 located within the chamber 182, and a pump 192 located outside the chamber 182.

The container 184 and the stirring device 186 are the same and serve the same function as the container 24 and stirring device 26 of the apparatus 20 in FIG. 1. Opposing ends of the coil 188 are connected to opposing terminals of the voltage source 190 so that the coil 188 is heated when the voltage source 190 is operated. The coil 188 is coated with a layer of material 194. The pump 192 is connected to the chamber 182 via a connection line 196.

In use, the pump 192 is operated until the pressure within the chamber 182 reduces to about 10-7 torr. The voltage source 190 is then operated so that the coil 188 is heated. The material 194 is typically silver which evaporates at a temperature of about 960° C. The coil 188 is heated to a temperature above 960° C., typically to about 1000° C. which causes evaporation of the silver material 194. The evaporated silver form coating particles 102 which move with linear trajectories away from the coil. A fraction of the coating particles move toward the superconductor particle 100 located within the container 184.

The apparatus 180, as with the apparatus 20 of FIG. 1, does not lend itself to large-scale production. It may however be possible to incorporate an evaporation system such as the coil 188 and the material 190 into an apparatus such as the apparatus 130 of FIG. 7, in which case the sputter target 142 may be removed. Sputtering however has certain advantages over evaporation. One advantage of sputtering is that a coating layer can be formed on superconductor particles at very low temperatures as previously described. Evaporation, by contrast, generally results in a coating layer being formed on superconductor particles at temperatures above 500° C., the temperature at which the superconductor particles 100 lose oxygen and thus their superconductor properties which could cause unwanted reaction between coating particles and the material of the superconductor particles. Another advantage of the use of sputtering is that deposition is multidirectional as described with reference to FIG. 2 and FIG. 8. Evaporation, by contrast, generally results in unidirectional deposition of coating layers on superconductor particles.

The further problem with the apparatus 180 in FIG. 12 is that the coating particles 102 do not only find their way onto the superconductor particles 100 but also find their way onto other components within the chamber 182 including any windows that are located on the chamber 182. FIG. 13 illustrates apparatus 180A which is essentially a modification of the apparatus 180 of FIG. 12. The apparatus 180 also includes a chamber 182A, a container 184A, a stirring device 186A, a voltage source 190A, a pump 192A, and a line 196A connecting the pump 192A to the chamber 182A. In addition, an enclosure 197 is located within the chamber 182A. The container 184A is located outside the enclosure 197. Opposing terminals of the voltage source 190A are connected to the enclosure 197. A conductive cup 198 is located within the enclosure 197. An outlet passage 199 is formed out of a lower surface of the enclosure 197. When the voltage source 190A is operated, current passes through the enclosure 197 and the cup 198. The current heats material 194A located within the cup 198, causing evaporation thereof. The evaporated material then attaches to inner surfaces of the enclosure 197. The current passing through the enclosure 197 heats the particles attached to the inner surface thereof, causing evaporation thereof into coating particles which leave the enclosure 197 in a downward direction. None of the coating particles move in sideways or upward directions. Side and upper surfaces of the chamber 192A are not covered by any coating particles. The coating particles attached to superconductor particles in the container 184A.

The foregoing description relates primarily to the manufacture of a three component composition as shown in FIG. 6. The three component composition includes superconductor particles 100, coating layers 110 on the superconductor particles 100, and a material 114 between the coated superconductor particles. In such a composition the superconductor particles 100 are generally relatively brittle and the material 114 is generally relatively ductile. Such a composition finds particular application in a composition wherein the superconductor particles 100 display superconductive characteristics at relatively high temperatures. In such a composition, the coating layers 110 are typically made of silver.

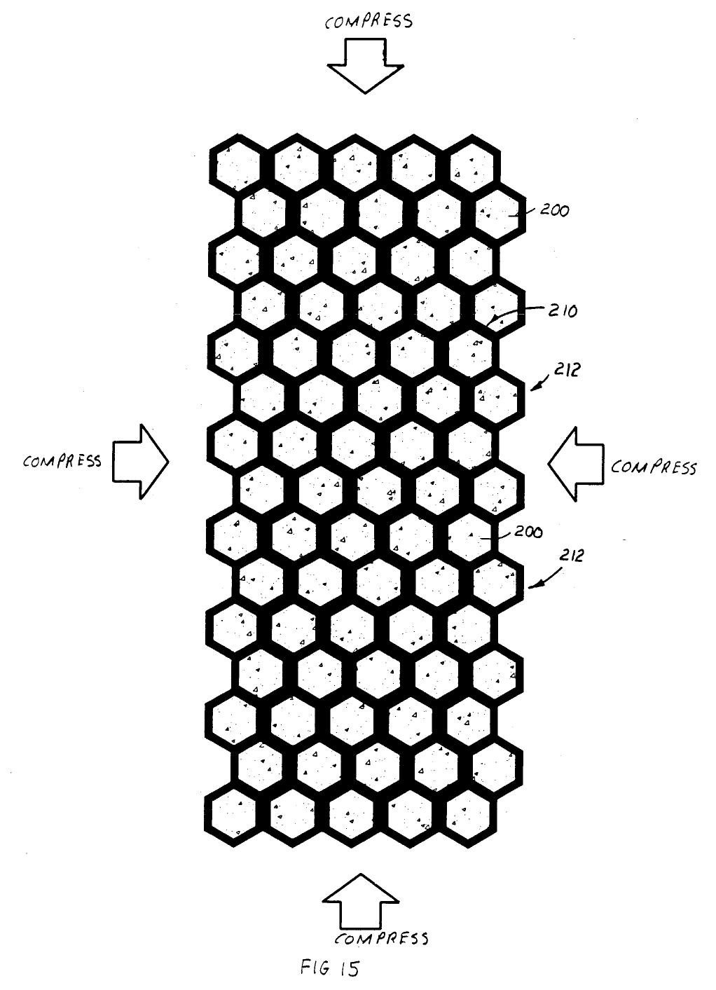

It should however be understood that the invention may also find application in the manufacture of a two component composition. FIG. 3 illustrates a plurality of superconductor particles 200 which are coated with coating layers 210. The coated particles 212 are loosely grouped together without a third material between them. As shown in FIG. 15, the coated particles 212 are then compressed into a composition wherein the layers 210 form interfaces between the superconductor particles 200. The coating layers 210 are typically not made of silver since silver cannot be driven to a superconductive state. Typical materials that can be driven to a superconductive state include niobium and its alloys, a niobium titanium alloy, lead and its alloys, a lead bismuth alloy, tin and its alloys, and indium and its alloys. These materials may however be more reactive with the first material than silver. Silver is also more permeable to oxygen allowing for replacement of oxygen into the first material if necessary.

Any one of the sputter target 28 in FIG. 1, the cylindrical sputter target 142 in FIG. 7, or the material 194 in FIG. 12 or the material 194A in FIG. 13 may be of these materials that can be driven to a superconductive state.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A method for producing a superconductor property composite, comprising:
forming a plurality of superconductor particles of a first material being relatively brittle and being selected to be in a superconductive state above 10K;
directing coating particles from a source of coating particles of a second material to the superconductor particles, while the superconductor particles are unsupported by any structure, thereby at least partially coating a surface of each unsupported superconductor particle with an initial coating layer to form a plurality of partially coated particles;
rotating each partially coated particle relative to the source before being supported by any structure, resulting in rotated particles;
directing coating particles from the source to the rotated particles before being supported by any structure, thereby further coating the respective surface of each superconductor particle with a further coating layer to form a plurality of further coated particles; and
supporting the further coated particles.

2. The method of claim 1, further comprising:
locating the further coated particles in proximity to a third material to form the composite, the third material being selected to be relatively ductile when compared to the first material and to be driven to a superconductive state by the first material when the first material is in a superconductive state and the third material is in proximity to the first material, the second material being selected to be substantially nonreactive with the first material and being sufficiently thin to allow for the third material to be driven to a superconductive state by the first material through the second material.

3. The method of claim 1, further comprising:
locating the superconductor particles in a chamber;
introducing gas particles into the chamber;
creating a voltage on a sputter target, the source being the sputter target, the sputter target being located in the chamber and being made of the second material, the gas particles being ionized and then attracted to the sputter target due to the voltage being created on the sputter target, the gas ions colliding with the sputter target so that the coating particles of the second material are released from the sputter target and directed from the sputter target to the superconductor particles so that the surface of each superconductor particle is coated with the at least one of the layers.

4. The method of claim 3, further comprising:
dropping the superconductor particles from a higher elevation to a lower elevation through a volume under a force of gravity, the coating particles being directed from the sputter target to the superconductor particles while dropping through the volume, thereby coating the surface of each superconductor particle with at least one of the layers; and
catching the superconductor particles at the lower elevation.

5. The method of claim 4 wherein the sputter target includes at least one component located on opposing sides of the volume.

6. The method of claim 5 wherein the sputter target forms an enclosure around the volume.

7. The method of claim 1, further comprising:
dropping the superconductor particles at least a first time from a higher elevation to a lower elevation through a volume under a force of gravity, the coating particles being directed from the source to the superconductor particles while dropping through the volume, thereby coating the surface of each superconductor particles with the at least one of the layers; and
catching the superconductor particles at the lower elevation.

8. The method of claim 7, further comprising:
transporting the superconductor particles back to the higher elevation; and
dropping the superconductor particles at least a second time from the higher elevation to the lower elevation through the volume under a force of gravity.

9. The method of claim 1 wherein the second material is silver.

10. The method of claim 1 wherein at least one of the layers is formed by simultaneously directing the coating particles onto each superconductor particle from a first direction and from a second direction being at an angle relative to the first direction, thereby simultaneously coating the surface of the superconductor particle with at least one of the layers in both the first and second directions.

11. The method of claim 1 wherein at least one of the layers is applied at a temperature below 500° C.

12. A method for producing a superconductor property composite, comprising:
forming a plurality of superconductor particles of a first material being relatively brittle and being selected to be in a superconductive state above 10K;
dropping the superconductor particles from a higher elevation to a lower elevation through a volume under a force of gravity;
directing coating particles from a source of coating particles of a second material to the superconductor particles while dropping through the volume and before catching the superconductor particles, thereby coating a surface of each superconductor particle with a coating layer to form a plurality of coated particles; and
catching the superconductor particles at the lower elevations.

13. The method of claim 12, further comprising:
locating the further coated particles in proximity to a third material to form the composite, the third material being selected to be relatively ductile when compared to the first material and to be driven to a superconductive state by the first material when the first material is in a superconductive state and the third material is in proximity to the first material, the second material being selected to be substantially nonreactive with the first material and being sufficiently thin to allow for the third material to be driven to a superconductive state by the first material through the second material.

14. A method for producing a superconductor property composite, comprising:
forming a plurality of superconductor particles of a first material being relatively brittle and being selected to be in a superconductive state above 10K;
applying a coating layer on a surface of each superconductor particle to form a plurality of coated particles, the coating layer being applied with the superconductor particles at a temperature below 500° C.

15. The method of claim 14, further comprising:
locating the further coated particles in proximity to a third material to form the composite, the third material being selected to be relatively ductile when compared to the first material and to be driven to a superconductive state by the first material when the first material is in a superconductive state and the third material is in proximity to the first material, the second material being selected to be substantially nonreactive with the first material and being sufficiently thin to allow for the third material to be driven to a superconductive state by the first material through the second material.

16. Apparatus for coating a plurality of superconductor particles, comprising:
a chamber;
a higher container for holding and dropping the superconductor particles from a higher elevation to a lower elevation through a volume in the chamber under a force of gravity;
a lower container located at the lower elevation to catch the superconductor particles after dropping through the volume;
a source of coating particles of a second material, the coating particles being directed from the source to the superconductor particles while dropping through the volume, thereby coating a surface of each superconductor particle with a coating layer to form a plurality of coated particles.

17. The apparatus of claim 16 further comprising:
a transporting device that collects the particles form the lower container and transports and delivers the particles to the higher container.

18. The apparatus of claim 16 further comprising:
a source of gas particles that introduces gas particles into the container, the source of coating particles being a sputter target within the chamber; and
a voltage source coupled to the sputter target so as to create a voltage on the sputter target, the gas particles being ionized and then attracted to the sputter target due to the voltage and colliding with the sputter target so that coating particles are released from the sputter target, the coating particles having movement directed towards the particles so that a coating layer is formed a surface of at least some of the particles.

19. The apparatus of claim 18 wherein the sputter target includes at least one component located on opposing sides of the volume.

20. The apparatus of claim 19 wherein the sputter target forms an enclosure around the volume.

21. The apparatus of claim 20 wherein the sputter target substantially entirely encloses the volume when viewed from above.
